(19) United States
(12) Patent Application Publication
(10) Pub. No.: US 2008/0061836 A1
(43) Pub. Date: Mar. 13, 2008

(54) Current Mirror and Parallel Logic Evaluation

(75) Inventor: Zhibin Cheng, Cary, NC (US)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: INTERNATIONAL BUSINESS MACHINES CORPORATION, Armonk, NY (US)

(21) Appl. No.: 11/466,139

(22) Filed: Aug. 22, 2006

(51) Int. Cl. H03K 19/096

(52) U.S. Cl. 326/97

(57) ABSTRACT

Methods, apparatuses, and systems to improve performance of integrated circuits are discussed. Some embodiments comprise methods to increase rates of logic evaluation in integrated circuits. The methods generally involve evaluating logic in one or more logic branches, where one of more of those branches employs a current mirror, and outputting a logic value through an output stage that also employs a current mirror. Other embodiments comprise apparatuses and circuits to reduce logic evaluation time in an integrated circuit, generally comprising one or more logic modules coupled to one or more current mirrors, where the current mirrors increase the discharge rates of logic elements in the integrated circuit and speed logic evaluation. Various embodiments have two or more logic modules to evaluate logic in parallel. Various embodiments may comprise “AND” and “NAND” logic circuits, such as dynamic “AND” and “NAND” gates.

### CROSS-REFERENCE TO RELATED APPLICATION

The present application relates to U.S. patent application Ser. No. 11/466,113, attorney docket number RPS920050122US1, assigned to the assignee of the present invention and filed concurrently herewith.

### FIELD

The present invention generally relates to the field of integrated circuits. More particularly, the present invention relates to methods and apparatuses to improve the performance of digital logic circuits, such as dynamic and domino logic, in integrated circuits.

### BACKGROUND

Designers of electronic circuits today employ a variety of different circuit types and circuit arrangements in designing modern circuits. Designers of high performance digital circuits, such as high performance very large scale integration (VLSI) circuits, extensively use two types of circuits formed with complimentary metal oxide semiconductor (CMOS) transistors. By and large VLSI circuit designers use static logic circuits because of their simplicity, robustness, noise-tolerance, and manufacturability. In static logic circuits, pull-up networks generally use p-type metal oxide semiconductor (p-MOS) transistors to raise output connections to Vdd, while pull-down networks often use n-type metal oxide semiconductor (n-MOS) transistors to lower output connections to Vss or ground.

Unfortunately, static logic is generally used only in circuits or circuit sections requiring low performance. Designers limit the use of static logic in high performance circuits for a variety of reasons, such as the problems of speed and clock skew. Static circuits tend to operate relatively slow because logic inputs must drive both n-MOS and p-MOS transistors. Frequently, only one of two transistors in a CMOS transistor pair will be on, with the other transistor loading the input. Additionally, p-MOS transistors are relatively large when compared to n-MOS transistors. This large area tends to add unwanted capacitance and slows transition times as the capacitance must be charged or discharged to bring associated logic levels high and low.

As the performance limitations of speed and clock skew in static logic circuits become more problematic, which often occurs in many high performance designs, they tend to impact design considerations and overall performance of the integrated circuits. As a result, designers often resort to dynamic logic circuits to overcome such problems. In dynamic logic circuits, dynamic gates formed from n-MOS transistors generally replace the larger and slower p-MOS transistors. The dynamic gates also usually have single clocked PMOS transistors that do not load the inputs.

The dynamic gate works or operates in two phases: a pre-charge phase and an evaluation phase. During the pre-charge phase, the clock input is usually low, turning off an “evaluate” n-MOS transistor and switching on a “pre-charge” p-MOS transistor. Consequently, this pulls the output high, as there is no path from the output to the ground. At this time, an arrangement of n-MOS transistors receives logic inputs from other parts of the circuit for evaluation. During the evaluation phase, the clock input is transitioned high, turning the “pre-charge” p-MOS transistor off and switching on the “evaluate” n-MOS transistor. At this point, the state of the output will depend on the state values of the inputs to the arrangement of n-MOS transistors. If any combination of n-MOS transistors provide a path to ground or to a low voltage then the output will transition low, otherwise it will remain high.

This method of evaluating logic inputs, using a clock signal to alternatively pre-charge and evaluate n-MOS inputs, tends to allow integrated circuits to operate appreciably faster than those only employing static logic. This increase in performance, however, comes with a cost. Dynamic logic circuits generally have numerous drawbacks and design difficulties. For example, designers using dynamic logic must continually confront problems of power and noise.

To combat these problems of power and noise, designers have developed numerous techniques that help minimize their impact. Various keeper related techniques have focused on reducing leakage currents, increasing throughput, and increasing noise immunity of high fan-in “OR” dynamic gates. Examples of such improved circuits are high-speed domino (HS-domino) circuits, conditional keeper circuits, and current mirror evaluation logic (CMEL) circuits. These circuits were developed to address tradeoffs between delay reduction and noise immunity. For many types of circuits, such as high fan-in “AND” dynamic gates, noise may not be as much as a concern as the problem of latency stemming from high-resistant discharge paths. Designers usually address the problem of latency due to high resistance in the discharge path by utilizing multi-stage dynamic logic. However, this approach degrades performance due to propagation delays through the stages.

With recent developments being aimed at lowering power consumption and increasing noise immunity, the problem of latency has not been adequately addressed. No existing technologies or techniques focus on reducing latency in dynamic logic gates having high-resistance discharge paths, such as high fan-in “AND” dynamic gates. Consequently, no existing design techniques or methods adequately address latency issues, or increase the rates of logic evaluation, for high fan-in gates having 16, 32, and 64 or more inputs. What are needed, therefore, are alternative methods, circuit apparatuses, and techniques to increase the rates of logic evaluation in integrated circuits, such as high fan-in dynamic gates.

### SUMMARY

The problems identified above are in large part addressed by methods, apparatuses, and systems to reduce latency in integrated circuits, including high performance processors and VLSI integrated circuits. One embodiment comprises a method to increase a rate of logic evaluation in integrated circuits. The method generally involves evaluating logic in one or more logic branches, where one of more of those branches employs a current mirror, and outputting a logic value through an output stage that also employs a current mirror. Alternative embodiments of the method comprise reducing parasitic diffusion capacitance associated with one or more of the logic branch current mirrors. Embodiments of the method may include solving logic simultaneously, in parallel, using numerous logic branches.

Another embodiment comprises an apparatus to reduce logic evaluation time in an integrated circuit. The apparatus generally comprises a logic module coupled to a current mirror, where the current mirror increases the discharge rate of logic elements in the logic module. One embodiment of the apparatus may have a capacitance reduction module coupled to the current mirror. Other embodiments of the apparatus may have two or more logic modules to evaluate logic in parallel. Various embodiments may comprise “AND” and “NAND” logic circuits, such as dynamic “AND” and “NAND” gates.

Yet another embodiment comprises an apparatus to increase logic evaluation speed in an integrated circuit, comprising at least one circuit branch, a current mirror to increase the discharge rate of a node in the circuit branch, an output circuit, and another current mirror to increase an operation rate of the output circuit. Alternative embodiments may include one or more field-effect transistors coupled to the circuit branches to reduce parasitic capacitance coupled to the branches. Different embodiments may employ p-MOS current mirrors and/or n-MOS current mirrors.

A further embodiment comprises a system having a power supply coupled to an integrated circuit, wherein the integrated circuit has one or more dynamic logic circuits with at least two logic evaluation branches to be operated in parallel, one or more current mirrors coupled to the logic evaluation branches, and an output circuit having a current mirror. Some embodiments of the system may have a processor, such as a high performance VLSI processor, for the integrated circuit. Other embodiments of the system may have an ASIC for the integrated circuit. Various embodiments may have different types of dynamic logic circuits, such as “AND” or “NAND” dynamic logic. Other embodiments may even evaluate combinations of “AND”, “OR”, and “NOT” dynamic logic.

### BRIEF DESCRIPTION OF THE DRAWINGS

Aspects of the invention will become apparent upon reading the following detailed description and upon reference to the accompanying drawings in which, like references may indicate similar elements:

FIG. 1 depicts a system that may employ current mirror parallel evaluation logic, comprising input and output modules, a processor, memory, circuit blocks, and a power supply;

FIG. 2 depicts an apparatus having a logic module and an output module employing two current mirrors;

FIG. 3 illustrates an embodiment of an eight-input dynamic “AND” gate employing two current mirrors;

FIG. 4 depicts an apparatus having two parallel logic modules employing two current mirrors coupled to an output module also employing a current mirror;

FIG. 5 illustrates an embodiment of a high fan-in dynamic “AND” gate employing three current mirrors, wherein the inputs are distributed among two parallel evaluation branches; and

FIG. 6 depicts a flowchart of a method to reduce logic evaluation time in an integrated circuit by employing parallel evaluation branches and current mirrors.

### DETAILED DESCRIPTION OF EMBODIMENTS

The following is a detailed description of example embodiments of the invention depicted in the accompanying drawings. The example embodiments are in such detail as to clearly communicate the invention. However, the amount of detail offered is not intended to limit the anticipated variations of embodiments; but, on the contrary, the intention is to cover all modifications, equivalents, and alternatives falling within the spirit and scope of the present invention as defined by the appended claims. The detailed descriptions below are designed to make such embodiments obvious to a person of ordinary skill in the art.

Generally speaking, methods, circuit apparatuses, and techniques to increase the rates of logic evaluation in integrated circuits are disclosed. New leakage latency reduction schemes for various types of integrated circuits, including dynamic logic circuits, which reduce latency are discussed. Embodiments comprise methods and apparatuses to reduce the time associated with logic evaluation in integrated circuits by employing parallel evaluation branches and current mirrors. The methods and apparatuses generally involve using one or more branches to receive logic inputs, so that the logic inputs may be evaluated in parallel when the number of inputs is relatively large. These methods and apparatuses employ current mirrors in both logic and output branches to speed the logic evaluation.

While portions of the following detailed discussion describe many embodiments comprising dynamic logic circuits, upon review of the teachings herein, a person of ordinary skill in the art will recognize that the following invention may be practiced and applied in a variety of integrated circuits, such as static logic arrangements and alternative dynamic circuits, such as Domino circuits. Various methods and apparatuses employing aspects of the invention are often interchangeable. Further, some discussions focus on high fan-in dynamic “AND” gates. One of ordinary skill in the art will recognize that alternative embodiments may comprise dynamic “NAND” gates, or other dynamic gates performing a variety of different logic functions. Such alternative embodiments as these and others should be considered to be substituted for the described embodiments when employed in accordance with similar constraints to perform substantially equivalent functions.

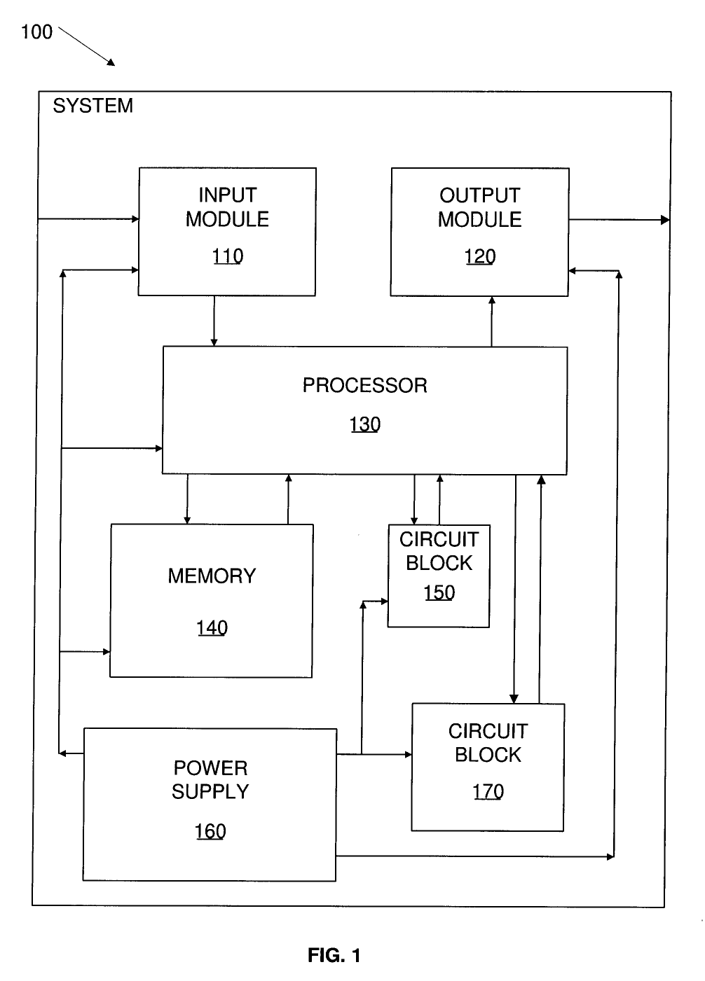

Turning to the drawings, FIG. 1 illustrates how a system 100 may benefit from methods and apparatuses described herein for increasing the rates of logic evaluation in integrated circuits (ICs). System 100 may comprise an application specific integrated circuit (ASIC), a VLSI high-performance central processing unit (CPU), or a standalone device such as a portable computing device. System 100 may be divided into numerous functional areas and comprise numerous components, such as input module 110, output module 120, processor 130, memory 140, and circuit blocks 150 and 170. System 100 may include power supply 160 to supply voltage and current to the elements of system 100. Power supply 160 may comprise a separately-housed power supply unit supplying power to system 100 or it may comprise a section of an integrated circuit wafer used to process and distribute power to the elements of system 100. For example, power supply 160 may comprise an integrated circuit arranged to receive a system voltage of 5 volts and distribute 5-volt power to input module 110 and output module 120, while stepping down the voltage to 3 volts for distribution and use within other modules, such as processor 130.

System 100 may need to process information, via processor 130 and/or circuit blocks 150 and 170, in a rapid manner. For example, system 100 may comprise an ASIC designed for high-speed data encryption and/or decryption. System 100 may receive digitally formatted data via input module 110 which needs to be rapidly encrypted and transmitted via output module 120. Processor 130 may receive bits or words of data from input module 110 and temporarily store them in memory 140. When a sufficient or predetermined quantity of data has accumulated in memory 140, processor 130 may retrieve the quantity of data and transfer it to circuit block 150. Circuit block 150 may receive the data block and encrypt it. Since the data needs to be rapidly encrypted in this example, circuit block 150 may comprise one or more current mirror parallel evaluation logic (CMPEL) circuits. In other words, circuit block 150 may comprise circuits having reduced latency times that are able to rapidly encrypt data and satisfy some performance demand for which system 100 may have been designed. Circuit block 150 may use the CMPEL circuits to encrypt the data block and send the encrypted data back to processor 130. Processor 130 may then either store the encrypted data in memory 140 or transmit it via output module 120.

As indicated, system 100 may also decrypt data. For example, system 100 may receive encrypted data via input module 110 and pass the data to circuit block 170 for decryption. Circuit block 170 may also employ CMPEL circuits to rapidly decrypt the data before outputting the data via output module 120. Alternatively, system 100 may store the decrypted data in memory 140 before outputting the data from output module 120.

In alternative embodiments, system 100 may employ circuit arrangements having increased rates of logic evaluation in other elements of system 100. For example, system 100 may employ CMPEL circuits in processor 130. System 100 may comprise a video graphics adapter in a multimedia-based computer or gaming console. Accordingly, processor 130 may need to rapidly process video display information. Processor 130 may receive raw video information from input module 110 and/or memory 140. Processor 130 may utilize one or more CMPEL circuits to convert or manipulate the video information before sending it to a display device via output module 120. For example, processor 130 may decode or uncompress video data “on the fly”, such as in the cases of video rasterization or processing Motion Picture Experts Group (mpeg) video data.

While the aforementioned examples discuss ASICs and high-performance processors, other systems and devices may also benefit may benefit from circuit apparatuses with increased rates of logic evaluation. For example, in alternative embodiments system 100 may comprise a high-speed communications processor or a high-performance data acquisition chip. System 100 may process analog data in addition to, or instead of, digital data. For example, system 100 may encode National Television Standards Committee (NTSC) analog formatted video data received by input module 110. Additionally, while the previous examples illustrated that circuit blocks 150 and 170, as well as processor 130, may employ circuit apparatuses having increased rates of logic evaluation, other elements of system 100 may also employ such circuit apparatuses. For example, input module 110 and output module 120 may have CMPEL circuits to handle high speed data received at input module 110 or transmitted from output module 120.

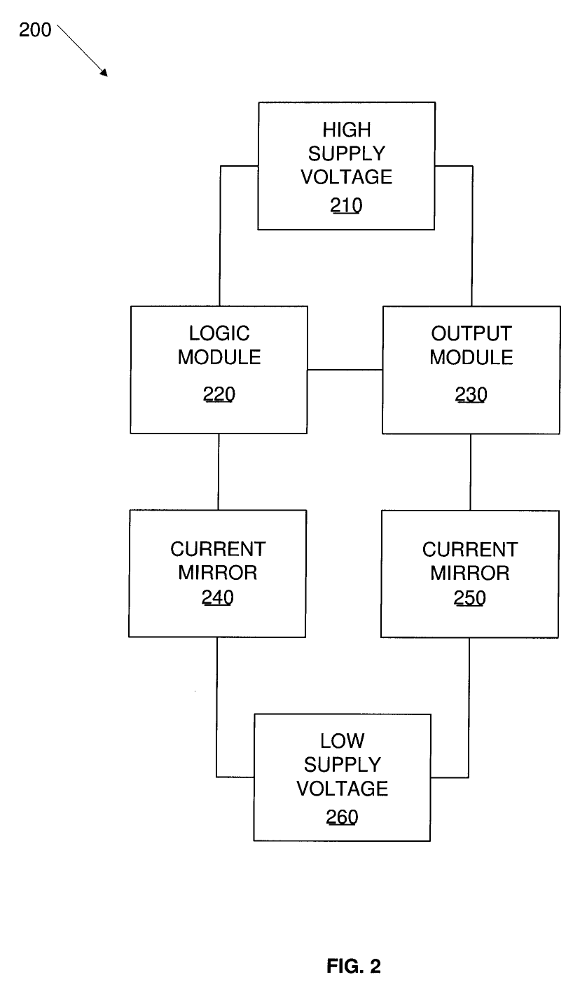

To see an example embodiment of the type of circuit or apparatus which may be used to increase a rate of logic evaluation in a system such as system 100, we turn to FIG. 2. FIG. 2 shows an apparatus 200 capable of evaluating logic in a rapid fashion having reduced latency. Apparatus 200 may be powered by a high supply voltage 210 and a low supply voltage 260. For example, in some embodiments high and low supply voltages 210 and 260 may comprise Vdd and Vss having an average voltage magnitude of 5 volts. In other embodiments, the average voltage magnitude may measure 3.3 volts, or other voltages, used to power integrated digital logic circuits. Even further, in some embodiments, high supply voltage 210 and low supply voltage 260 may comprise power supply components, such as rectifying bridges and capacitors, located in physically separate housings from the remaining components of apparatus 210. In other embodiments, high supply voltage 210 and low supply voltage 260 may comprise metal traces of an integrated circuit.

High supply voltage 210 and low supply voltage 260 may provide operating power to a logic module 220, an output module 230, and current mirrors 240 and 250. When apparatus 200 is powered up and operating, logic module 220 may receive numerous digital inputs. For example, logic module 220 may receive 3, 8, 16, or more inputs, as well as another number of digital inputs. Logic module 220 may receive such inputs and perform various types of logic functions. For example, logic module 220 may receive 8 digital inputs and perform an “AND” function. In other words logic module 220 may produce a logical low for different combinations of highs and lows for the 8 inputs, unless all eight are logically high. If all 8 inputs are logically high when logic module 220 performs an evaluation, logic module 220 may then produce a logical high and transmit the logical high to output module 230.

As indicated, logic module 220 may have numerous digital inputs to be evaluated. To reduce latency during a logic evaluation phase, apparatus 200 may be configured to trigger or activate current mirror 240. For example, if logic module 220 comprises dynamic logic gates that have been pre-charged, apparatus 200 may manipulate current mirror 240 so as to increase a rate of charge dissipation when logic module 220 enters the subsequent evaluation phase.

In some embodiments, logic module 220 may comprise dynamic logic, such as domino logic. In alternative embodiments, however, logic module 220 may comprise static logic. Additionally, various types of digital gate technologies may form the logic gate circuitry of logic module 220. For example, one may create the logic gate circuitry of logic module 220 using 90 or 250 nanometer (nm) CMOS technology. Alternatively, one may form the logic gate circuitry of logic module 220 using a substantially different technology, such as 180 or 500 nm Silicon Germanium (SiGe) BiCMOS or another technology.

Output module 230 may receive the evaluated logic signal from logic module 220 and perform a number of functions with it. For example, output module 230 may invert the evaluated logic signal as may be necessary if apparatus 200 is part of a domino logic circuit, such as a HS-domino logic circuit. Alternatively, output module 230 may capture the evaluated logic signal from logic module 220 and perform some type of signal operation on it, such as enhancing its voltage magnitude or coupling it to devices capable of driving numerous output devices connected to output module 230.

In different embodiments, communication between logic module 220 and output module 230 may be unidirectional or bidirectional. In the case of unidirectional communication, output module 230 may only receive logic and other types of signals from logic module 220. For example, logic module 220 may transmit an evaluated logic signal to output module 230. In such a case, logic module 220 may receive no signals back from output module 230. In the case of bidirectional communication, logic module 220 may transmit the evaluated logic signal to output module 230 only in response to receiving a “ready” signal transmitted back from output module 230. Such feedback signal may be necessary, for example, when dynamic charges present in output module 230 may serve to inject noise into logic module 220. In this scenario, the feedback signal may operate an isolation transistor, such as a p-type or n-type transistor which isolates logic module 220 from output module 230 until output module 230 is in the proper state.

Current mirrors 240 and 250 may speed the operation of logic module 220 and output module 230, respectively. As mentioned above, current mirror 240 may reduce the latency of evaluating logic in logic module 220. Current mirror 240 may operate cyclically, such as during the evaluation phases associated with dynamic logic arrangements, or current mirror 240 may operate continuously, such as may be the case with static logic. Similar to the performance enhancement attributed to current mirror 240 for logic module 220, current mirror 250 may speed the operation of output module 230. For example, if output module 230 captures or inverts the evaluated logic signal from logic module 220, current mirror 250 may speed the circuits that capture or invert the signal.

Additional circuit elements, such as resistors and transistors, may couple to current mirrors 240 and 250 to perform auxiliary functions. For example, a transistor may operate in parallel with current mirror 240 to reduce undesired capacitance effects due to the circuit arrangement. Furthermore, various embodiments may employ different types of current mirrors. For example, one embodiment may employ an n-MOS current mirror for current mirror 240 and employ a p-MOS current mirror for current mirror 250. Other embodiments may employ various combinations of current mirror types, such as both current mirrors being n-MOS current mirrors.

As depicted in FIG. 2, current mirror 240 may not directly interact with current mirror 250. In other embodiments, however, current mirror 240 may communicate or send signals to current mirror 250, and vice-versa. For example, circuitry coupled to current mirror 240 may detect when dynamic logic in logic module 220 has been sufficiently evaluated such that output module 230 may accept the evaluated logic signal from logic module 220. Upon sufficient evaluation, current mirror 240 may communicate this status to current mirror 250, triggering the delay reduction actions of current mirror 250.

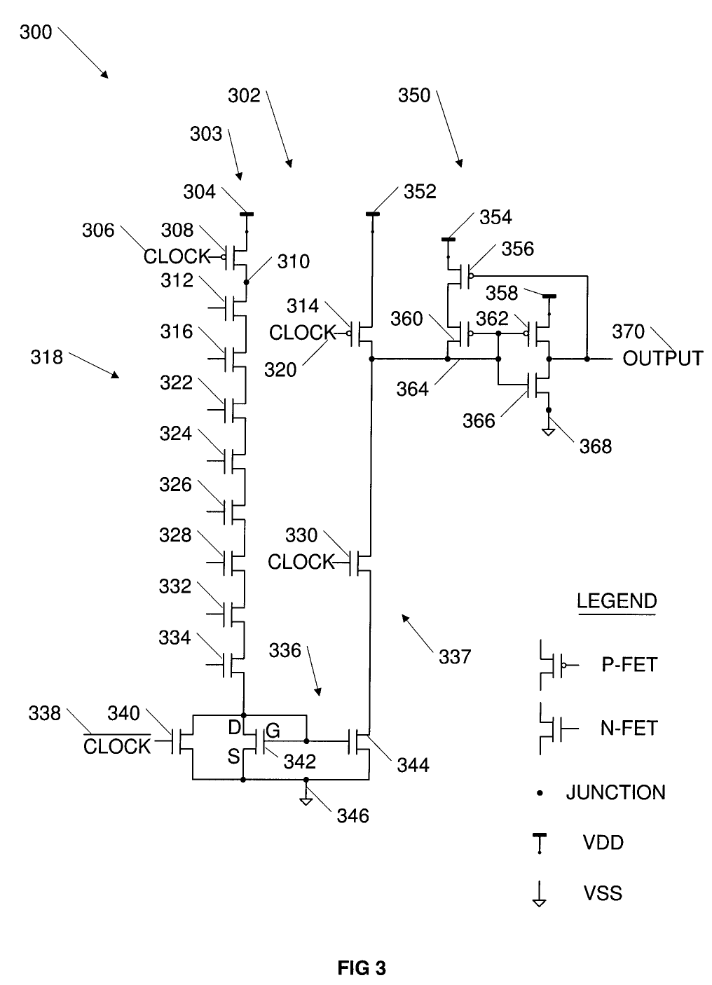

For an example of an embodiment which may be one specific implementation of apparatus 200, we turn now to FIG. 3. FIG. 3 illustrates an embodiment of a two-stage current mirror circuit 300 to increase a rate of logic evaluation in an integrated circuit. The two-stage current mirror circuit 300 is divided into two stages, first stage 302 and second stage 350. First stage 302 may perform logic evaluation for circuit 300. Upon evaluating logic in first stage 302, second stage 350 may accept the evaluated logic and facilitate its transmission to circuits external to circuit 300.

First stage 302 comprises an array of logic inputs 318 in a first circuit branch 303. More specifically, the array of logic inputs 318 comprises a series of eight n-MOS transistors (312, 316, 322, 324, 326, 328, 332, and 334). Arranged in this manner, the array of logic inputs 318 may operate as a logical “AND” gate. Stated differently, as depicted, first stage 302 may perform a dynamic “AND” gating function. During a pre-charge phase, clock signal 306 may be low. A low applied to a gate of p-MOS transistor 308 will forward bias it, or turn it on, and raise the voltage of evaluation node 310. Also during the pre-charge phase, inverted clock signal 338 may be high. As depicted in FIG. 3, a channel of n-MOS transistor 342 is coupled between the array of logic inputs 318 and power supply Vss connection 346. A high applied to a gate of n-MOS transistor 340 will forward bias n-MOS transistor 340, effectively coupling the voltage potential of Vss connection 346 to the gate of n-MOS transistor 342 when at least one of the n-MOS transistors in the array of logic inputs 318 is reverse-biased. Arranged in this fashion, n-MOS transistor 340 may be appropriately sized and serve to clean up internal parasitic diffusion capacitances at the source terminal of n-MOS transistor 334. In alternative embodiments, other elements may combine to form a different and/or more complex capacitance reduction module, such as an arrangement of transistor instead of a single n-MOS 340 transistor.

During the pre-charge phase, digital inputs to the array of logic inputs 318 may transition high and low in various combinations. Also during this pre-charge phase, second stage 350 will tend to hold output 370 of the output circuit, or second stage 350, low until the evaluation phase. Clock signal 320 will be low causing p-MOS transistor 314 to turn on while n-MOS transistor 330 is conversely turned off. Turning p-MOS transistor 314 on couples power supply Vdd connection 352 to second stage evaluation node 364 and raises it high. Bringing evaluation node 364 high applies a high to the gate of p-MOS transistor 360, turning it off. However, when evaluation node 364 is high n-MOS transistor 366 turns on and couples output 370 to Vss connection 368 pulling output 370 low. In this pre-charge state, a low voltage will be applied to the gate of p-MOS transistor 356 and turn it on. However, high voltages will be applied to the gates of p-MOS transistor 360 and p-MOS transistor 362, turning them off and isolating Vdd connections 354 and 358 from the rest of second stage 350.

To illustrate how a current mirror may help increase the rate of operation of circuit 300, a short description of how n-MOS transistor 342 operates is in order. As long as the voltage from the gate to the source terminal of n-MOS transistor 342 is less than the threshold voltage, n-MOS transistor 342 will be in the off state. Whenever the voltage from the gate to the source terminal is greater than the threshold voltage but the voltage from the drain to the source is less than the drain-to-source pinch-off voltage, n-MOS transistor 342 will be on and operating in the ohmic region. Whenever the voltage from the gate to the source terminal is greater than the threshold voltage and the voltage from the drain to the source is greater than the drain-to-source pinch-off voltage, n-MOS transistor 342 will be on and operating in the saturation region.

One will note that the gate of n-MOS transistor 342 is tied to the drain terminal of n-MOS transistor 342. In this arrangement, the drain-to-source voltage of n-MOS transistor 342 will substantially equal the gate-to-source voltage. Again, as long as the gate-to-source voltage is greater than the threshold voltage n-MOS transistor 342 will be on and operating in the saturation region. n-MOS transistor 342 may continue to operate in this state of saturation up to its cut-off point. As will be explained, the gate potential of n-MOS transistor 342 will depend on the state of clock signal 306 and the state of the array of logic inputs 318. Since the gate of n-MOS transistor 344 is coupled to the gate of n-MOS transistor 342, n-MOS transistor 342 and n-MOS transistor 344 may therefore operate in tandem and operate as a current mirror 336. As n-MOS transistor 342 may turn on and drain any charge accumulated in the first circuit branch 303, n-MOS transistor 344 may similarly turn on and drain any charge accumulated in second circuit branch 337.

When clock signal 306 transitions high and inverted clock signal 338 correspondingly transitions low, first stage 302 will start the evaluation phase of the array of logic inputs 318. A high clock signal 306 applied to the gate of p-MOS transistor 308 will turn it off, isolating evaluation node 310 from power supply Vdd connection 304. Whether or not evaluation node 310 drops from a high to a low will depend on the individual states in the array of logic inputs 318. If any one of the transistors in to the array of logic inputs 318 is reverse-biased, in other words a low voltage is applied to any of the gates of the n-MOS transistors in the array of logic inputs 318, then a high will not be applied to the drain terminal of n-MOS transistor 342 and current mirror 336 will not be “activated” to drain the charge from evaluation node 310 during the evaluation phase. Additionally, a high will not be applied to the gate of mirror n-MOS transistor 344. Evaluation node 364, charged to a high during the pre-charge phase as described above, will remain high even though n-MOS transistor 330 is on, since n-MOS transistor 344 will be turned off.

If all of the inputs to the gates of the n-MOS transistors in the array of logic inputs 318 go high, then a series of events occur to change output 370 from its pre-charge low state to an evaluation high state. Again, during this evaluation phase, clock signal 306 will go low turning off p-MOS transistor 308 and isolating the high potential of Vdd connection 304 from the array of logic inputs 318. However, since all of the inputs to the array of logic inputs 318 are now high, a high voltage will be applied to the gates of both n-MOS transistor 342 and n-MOS transistor 344. n-MOS transistor 342 will start discharging the accumulated charges of the n-MOS transistors in the array of logic inputs 318. Simultaneously, n-MOS transistor 344 will immediately start discharging evaluation node 364 and pulling it low. Note that discharging evaluation node 364 may occur much faster due to the action of current mirror 336, since the charge of evaluation node 364 only has to dissipate through n-MOS transistor 330 instead of numerous transistors. In other words, evaluation node 364 may discharge much more rapidly due to the operation of current mirror 336 and absence of numerous n-MOS transistors, such as the n-MOS transistors in the array of logic inputs 318.

When n-MOS transistor 344 draws evaluation node 364 low, n-MOS transistor 336 will turn off and isolate the low voltage of Vss connection 368 from output 370. Additionally, a low evaluation node 364 will turn on p-MOS transistors 360 and 362. Turning on p-MOS 362 will couple the high voltage of Vdd connection 358 to output 370, raising output 370 high. Note that the rate of charging output 370 may be relatively fast due to the effect of the second stage current mirror.

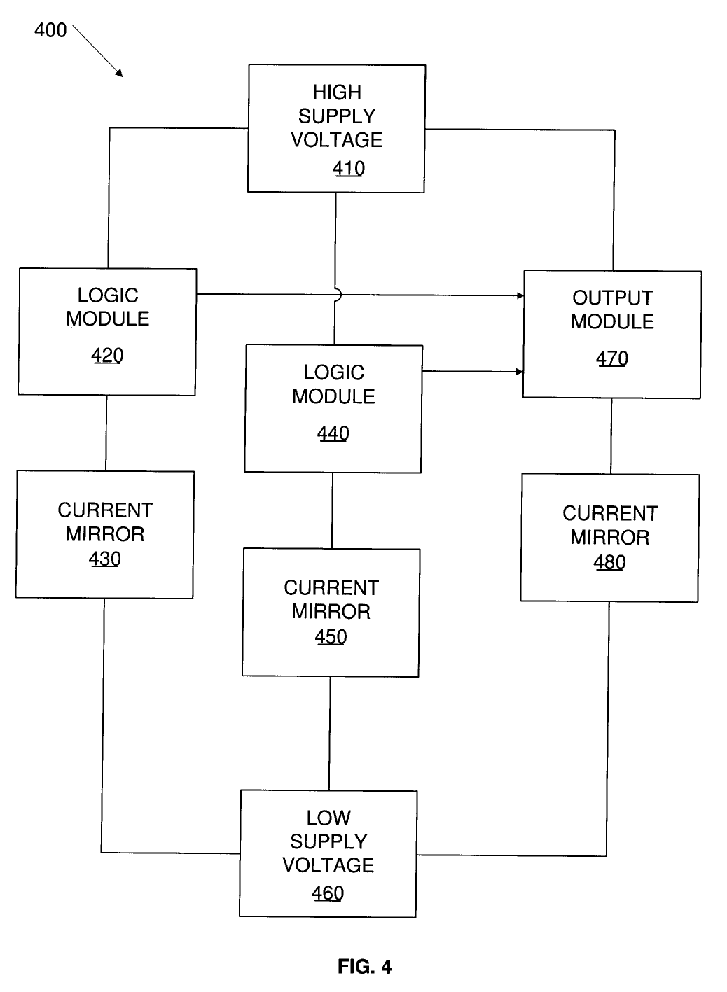

As noted above, FIG. 3 illustrates an embodiment of a two-stage current mirror circuit 300 to increase a rate of logic evaluation in an integrated circuit. The way two-stage current mirror circuit 300 is arranged may provide a good foundation for parallelism, allowing an integrated circuit designer to increase rates of evaluating even larger numbers of logic inputs while minimizing the negative effects of large amounts of resistance in discharge paths. To illustrate this concept, we turn now to FIG. 4.

FIG. 4 shows an embodiment of a current mirror parallel evaluation logic (CMPEL) apparatus 400. CMPEL apparatus 400 may comprise one logic solving portion of a complex integrated circuit needing to rapidly evaluate large quantities of digital logic inputs. For example, CMPEL apparatus 400 may comprise a circuit in a high-performance processor chip designed for predicting or forecasting weather. Weather forecasting applications often require analyzing large quantities of data and spotting trends for what the weather will be in the future. The integrated circuit containing CMPEL apparatus 400 may have only one such apparatus or it may have two, ten, or one-hundred such apparatuses.

To supply power to its elements, CMPEL apparatus 400 has a high supply voltage 410 and a low supply voltage 460. In some embodiments, high and low supply voltages 410 and 460 may supply 10 volts to the elements of CMPEL apparatus 400. In other embodiments high and low supply voltages 410 and 460 may supply other voltages, such as 3.3 volts. High supply voltage 410 and low supply voltage 460 may merely represent metal traces having the respective high and low voltages, or they may represent voltage regulation circuits in a dedicated power section of the integrated circuit containing CMPEL apparatus 400.

In the embodiment depicted, CMPEL apparatus 400 has the ability to evaluate two sets of logic in parallel. Logic module 420 may receive a first set of digital logic inputs for evaluation. Using current mirror 430 to speed evaluation, logic module 420 may statically or dynamically evaluate the logic inputs brought into logic module 420 and send a first logic output signal to output module 470. In a parallel fashion, logic module 440 may receive a second set of digital logic inputs for evaluation. Using current mirror 450 to speed evaluation, logic module 440 may also dynamically or statically evaluate the logic inputs brought into logic module 440 and send a second logic output signal to output module 470.

Output module 470 may accept the two signals corresponding to the evaluated logic from logic module 420 and logic module 440 and generate a final output signal to be distributed to other parts of the integrated circuit containing CMPEL apparatus 400. Additionally, current mirror 480 may speed the operation of output module 470. For example, CMPEL apparatus 400 may be arranged to accept a large number of inputs and comprise a high fan-in dynamic “NAND” gate. If all of the inputs to logic module 420 are all high, logic module 420 may send a logical high signal to output module 470. Similarly, if all of the inputs to logic module 440 are all high, logic module 440 may send a logical high signal to output module 470. Output module 470 may generate a high output whenever either one of the signals from logic modules 420 and 440 are low, but use current mirror 480 to rapidly generate a low voltage output when both signals are high.

As shown in FIG. 4, CMPEL apparatus 400 is arranged to evaluate two sets of logic in parallel. Other embodiments may have three, five, or even greater numbers of branches for evaluating logic in parallel. For example, logic module 420 may accept eight inputs, logic module 440 may accept six more inputs, and a third logic module may accept twelve more inputs. Each logic module may evaluate its respective logic inputs and send an individual logic evaluation signal to output module 470 for final processing and generation of a final output signal.

Each of the parallel logic modules may perform the same type of logic evaluation or each may perform different types of logic evaluation. For example, logic module 420 may receive eight inputs and perform a logical “AND” operation. In other words, logic module 420 may generate a low output at all times any of the inputs is low and generate a high output only when all eight inputs are high. Logic module 440 may accept six inputs and perform a logical “OR” operation. Logic module 440 may therefore generate a high output when any single one of the six inputs is high. Logic module 420 may perform its “AND” operation while logic module 440 simultaneously, or substantially simultaneously, performs its “OR” operation.

In further embodiments, logic module 420 and/or logic module 440 may perform multiple types of logic evaluation. For example logic module 420 may receive eight inputs and perform a logical “AND” operation of six of them and a logical “OR” on the remaining two inputs. Logic module 420 may generate a logical high output, therefore, when all of the first six inputs are high and at least one of the remaining two inputs is also high. Additionally, logic module 440 may receive eight more digital inputs and perform a logical “XOR” operation on four of the inputs and perform a logical “OR” on the remaining four inputs.

As described in the preceding examples, each of the logic modules may accept different numbers of inputs in different embodiments. For example, in some embodiments logic module 420 may receive eight inputs for logic evaluation while in other embodiments it may receive another number of inputs, such as six. Further, some embodiments may employ dynamic logic circuits for the logic modules while other embodiments may alternatively employ static logic circuits for one or more of the logic modules. For example, one embodiment of CMPEL apparatus 400 may employ a dynamic logic circuit for logic module 420 while employing a static logic circuit for logic module 440. Additionally, alternative embodiments may vary the number of current mirrors employed for the logic modules. For example, some embodiments may have four logic modules being assisted by two current mirror circuits, instead of one current mirror for each logic circuit.

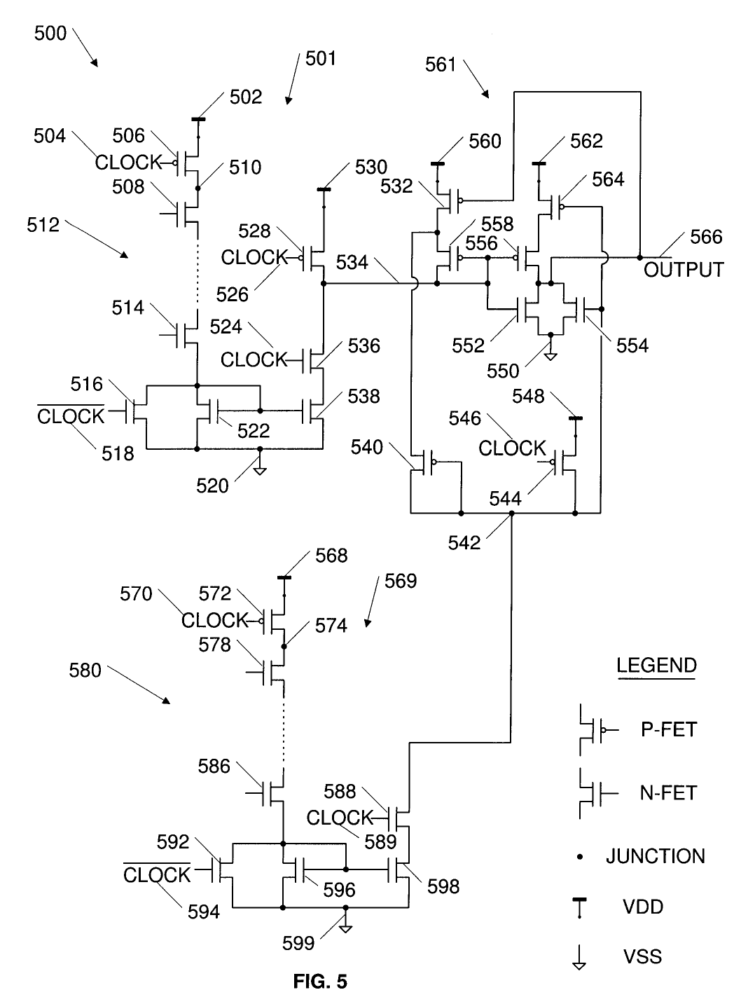

We continue our discussion by examining FIG. 5. FIG. 5 illustrates an embodiment of a CMPEL circuit 500 to increase a rate of logic evaluation in an integrated circuit. CMPEL circuit 500 has a first circuit branch 501 and a second circuit branch 569 to evaluate logic in parallel. In other words, first circuit branch 501 may receive an array of digital inputs 512 and evaluate them, while second circuit branch 569 receives a separate array of digital inputs 580 and evaluates them. Upon evaluating logic inputs in first circuit branch 501 and second circuit branch 569, output circuit 561 may accept the evaluated logic signals and generate a corresponding output signal at output 566.

### Operation of First Circuit Branch

As noted, first circuit branch 501 comprises array of digital inputs 512. FIG. 5 illustrates that array of digital inputs 512 comprises a series of n-MOS transistors, such as n-MOS transistors 508 and 514. Arranged in this manner, array of digital inputs 512 may operate to perform a dynamic “AND” logic operation. During a pre-charge phase, clock signal 504 may be low. A low applied to a gate of p-MOS transistor 506 will forward bias it, or turn it on, and raise the voltage potential of evaluation node 510. Also during the pre-charge phase, inverted clock signal 518 may be high. A high applied to a gate of n-MOS transistor 516 may forward bias it and couple the low voltage potential of Vss connection 520 to the gate of n-MOS transistor 522. Arranged in this fashion, n-MOS transistor 516 may form a capacitance reduction module, which may clean up internal parasitic diffusion capacitances associated with n-MOS transistors 522 and 538.

During the pre-charge phase, digital inputs to the array of digital inputs 512 may transition high and low in various combinations. During this pre-charge phase, first circuit branch 501 may tend to hold evaluation node 534 high until the evaluation phase. Clock signal 526 may be low causing p-MOS transistor 528 to turn on while clock signal 524 turns off n-MOS transistor 536. Turning p-MOS transistor 528 on couples power supply Vdd connection 530 to evaluation node 534 and raises it high.

### Operation of Second Circuit Branch

Similar to first circuit branch 501, second circuit branch 569 also has its array of digital inputs 580. Also similar to first circuit branch 501, the array of digital inputs 580 comprises a string of series connected n-MOS transistors, including n-MOS transistors 578 and 586. Arranged in this manner, the array of digital inputs 580 may also work to form a second part of the dynamic “AND” gate. In other words, the logic inputs to first circuit branch 501 and the logic inputs to second circuit branch 569 may combine to form one large “AND” gate input array.

During the pre-charge phase, clock signal 570 may be low. A low applied to the gate of p-MOS transistor 572 turns it on and raises the voltage potential of evaluation node 574. Also during the pre-charge phase, inverted clock signal 594 may be high. A high applied to the gate of n-MOS transistor 592 may forward bias it and couple the low voltage potential of Vss connection 599 to the gates of n-MOS transistor 596 and 598, which may help clean up the internal parasitic diffusion capacitances present at the drain terminal of n-MOS transistor 596.

Like the digital inputs to the array of digital inputs 512, digital inputs to the array of digital inputs 580 may transition high and low in various combinations during the pre-charge phase. During this pre-charge phase, second circuit branch 569 may tend to hold evaluation node 542 high until the evaluation phase. Clock signal 546 may be low causing p-MOS transistor 544 to turn on while clock signal 589 turns off n-MOS transistor 588. Turning p-MOS transistor 544 on couples power supply Vdd connection 548 to evaluation node 542 and raises it high.

### Evaluation of First and Second Circuit Branches

When the clock signals transition high and the inverted clock signals correspondingly transition low, then first circuit branch 501 and second circuit branch 569 may start the evaluation phase of the arrays of digital inputs 512 and 580. High clock signals 504 and 570 applied to the gates of p-MOS transistors 506 and 572 will turn them off, isolating evaluation nodes 510 and 574 from power supply Vdd connections 502 and 568. Whether or not evaluation nodes 510, 574, 534, and 542 drop low will depend on the individual states in the arrays of digital inputs 512 and 580. If a low voltage is applied to any of the gates of the n-MOS transistors in the array of digital inputs 512, then a high will not be applied to the gate terminal of n-MOS transistor 522 and the current mirror comprising n-MOS transistors 522 and 538 will not be triggered to rapidly drain the charge from evaluation node 534. Similarly, a low voltage applied to any of the gates in the array of digital inputs 580 will not apply a high the gates of n-MOS transistors 596 and 598. The current mirror comprising n-MOS transistors 596 and 598 will therefore not be triggered to rapidly drain the charge from evaluation node 542. Evaluation nodes 534 and 542, charged high during the pre-charge phase, will remain high unless all of the n-MOS transistors in either of the respective array of digital inputs are high and trigger the respective current mirror to draw either of them low.

### Operation of Output Circuit

As noted, evaluation nodes 534 and 542 will be drawn to logically high states during the pre-charge phase. Clock signals 526 and 546 will be low in the pre-charge phase, turning on p-MOS transistors 528 and 544 and pulling evaluation nodes 534 and 542 high. When evaluation node 534 is high, output stage current mirror p-MOS transistors 558 and 556 will be turned off but n-MOS transistor 552 will be turned on. When n-MOS transistor 552 is on, it will couple the low voltage of Vss connection 550 to output 566 and pull output 566 low. When evaluation node 542 is high p-MOS transistor 540 will be turned off and isolate the voltage potential of evaluation node 542 from the drain terminal of p-MOS transistor 558. A high voltage at evaluation node 542 will also turn on n-MOS transistor 554 to pull output 566 low, complementing the operation of n-MOS transistor 552. When output 566 is low, p-MOS transistor 532 will be turned on and couple the high potential of power supply Vdd connection 560 to the drain terminal of p-MOS transistor 540. This high potential at the drain terminal will be isolated from the source terminal, however, as long as p-MOS transistor 540 remains reverse-biased.

If all of the array of digital inputs 512 are high, the “AND” operation of first circuit branch 501 will be satisfied. In this case, evaluation node 534 may be drawn low in the manner previously described. When evaluation node 534 transitions low, p-MOS transistors 558 and 556 will both start turn on, while n-MOS transistor 552 turns off. However, assuming evaluation node 542 is still high at this point, switching p-MOS transistor 558 on will not change the state of output 566 since switching p-MOS transistor 558 on will only couple an indeterminate voltage to output 566. In other words, a single output signal change of state from first circuit branch 501 will not change the state of output 566. To see the condition upon which output 566 will change states, we need to see how the output operates when second circuit branch 569 changes its output state.

If all of the array of digital inputs 580 are high, the “AND” operation of second circuit branch 569 will be satisfied. In this case, evaluation node 542 will be drawn low in the manner described before. When evaluation node 542 transitions low, n-MOS transistor 554 will turn off, isolating the low voltage of Vss connection 550 from output 566 through n-MOS transistor 554. Additionally, p-MOS transistor 564 will switch on and couple the high potential of power supply Vdd connection 562 to the drain terminal of p-MOS transistor 556. However, output 566 may not change states because p-MOS transistor 556 may still be turned off if evaluation node 534 is still high. In other words, if the logic of second circuit branch 569 performs the “AND” operation and evaluates to a positive logic result and transitions its output from high to low, output 566 may not change from a low output to a high if the output from first circuit branch 501 has not changed states. In the event that both first circuit branch 501 and second circuit branch 569 both evaluate their respective logic inputs and end up changing the states of evaluation node 534 and evaluation node 542, respectively, then output 566 may change from low to high.

One should note that while the above description for the operation of CMPEL circuit 500 described the operation of a parallel “AND” dynamic logic gate, other embodiments may implement other types of logic arrangements. For example, in some embodiments first circuit branch 501 may be rearranged to perform a “NAND” function. Second circuit branch 569 may also perform a “NAND” operation in this embodiment, while in others it may perform another logical operation, such as an “XOR” operation.

FIG. 5 illustrates that the array of digital inputs 512 and the array of digital inputs 580 may have varying numbers of digital inputs. In some embodiments both arrays may receive eight inputs each. In other embodiments each array may receive fewer or more digital inputs. Additionally, each array may receive different numbers of inputs than the other array. For example one array may receive six inputs while the other array receives eight inputs. Even further, the number of circuit branches may vary in different embodiments. For example, one embodiment may have two additional circuit branches, in addition to first and second circuit branches 501 and 569, for a total of four circuit branches. If each circuit branch receives eight inputs, the overall embodiment may therefore be capable of evaluating thirty-two digital inputs in a rapid manner.

Also, while the embodiment shown in FIG. 5 has n-MOS current mirrors in the circuit branches and a p-MOS current mirror in the output stage, alternative embodiments may employ different current mirror arrangements. For example, second circuit branch 569 may employ a p-MOS current mirror while output stage 569 employs an n-MOS current mirror. Even further, the types of current mirrors employed may also differ in alternative embodiments. For example, instead of implementing a simple current mirror comprising two transistors in one or more of the circuit branches, alternative embodiments may implement current mirrors having three or more transistors. In other words, alternative embodiments may implement current mirror arrangements which are more complex than the current mirrors depicted in FIG. 5.

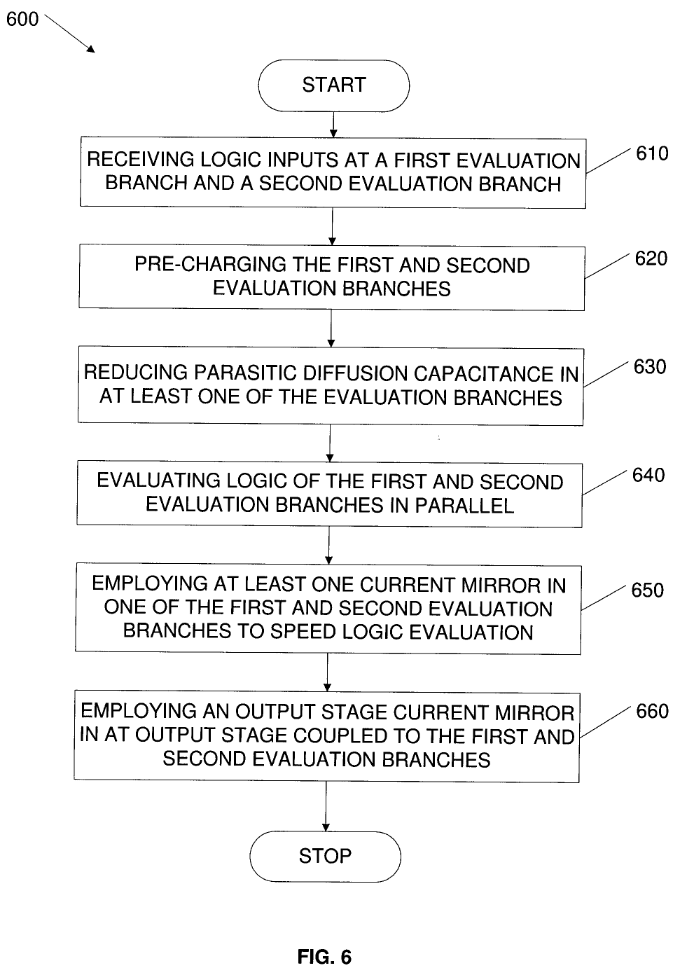

FIG. 6 depicts a flowchart 600 illustrating an embodiment of a method to increase rates of logic evaluation in an integrated circuit. Flowchart 600 begins with receiving logic inputs at a first evaluation branch and a second evaluation branch (element 610). For example, each of the two evaluation branches may receive eight inputs to be logically evaluated in an “AND” operation.

After receiving the logic inputs (element 610), an embodiment according to flowchart 600 may continue by pre-charging the first and second evaluation branches (element 620). Elaborating on the example above, each of the first and second evaluation branches may receive digital inputs for dynamic “AND” logic evaluation, requiring that each branch be charged before logic evaluation. Some embodiments may pre-charge both evaluation branches simultaneously, while other embodiments may start pre-charging one evaluation branch before the other. Additionally, an embodiment according to flowchart 600 may reduce parasitic diffusion capacitance in at least one of the evaluation branches (element 630). For example, a capacitance reduction module may reduce parasitic diffusion capacitance associated with the second evaluation branch. Some embodiments may also reduce parasitic diffusion capacitance associated with the first evaluation branch using the same capacitance reduction module or using another capacitance reduction module. Even further, some alternative embodiments may not reduce parasitic diffusion capacitance associated with any of the evaluation branches.

Upon pre-charging the evaluation branches and reducing parasitic diffusion capacitance in at least one of the evaluation branches (elements 620 and 630), a method according to flowchart 600 may continue by evaluating logic of the first and second evaluation branches in parallel (element 640). In other words, the pre-charging of each evaluation branch may conclude and evaluation in each branch may commence. In evaluating the logic in parallel, logic in one branch may be evaluated at substantially the same time and may be evaluated independently. Such logic evaluation may begin simultaneously, or begin at different times.

The method of flowchart 600 may also employ at least one current mirror in one of the first and second evaluations to speed logic evaluation (element 650). Some embodiments may employ current mirrors in each evaluation branch. Alternative embodiments may have one or more evaluation branches that do not employ any current mirrors. A method of flowchart 600 may employ an output stage current mirror in an output stage coupled to the first and second evaluation branches (element 660). For example, an embodiment may have two output stages coupled to two evaluation branches. Each of the output stages may have an output stage current mirror.

One skilled in the art of integrated circuit design will readily appreciate the flexibility and benefits that the aforementioned example methods and apparatuses provide for increasing the rate of logic evaluation in integrated circuits. The specifically described examples are only a few of the potential apparatus and circuit arrangements wherein current mirrors may be operated in parallel evaluation branches to decrease the latencies or delays of logic evaluation in integrated circuits.

It will be apparent to those skilled in the art having the benefit of this disclosure that the present invention contemplates methods, apparatuses, and systems that may increase the performance of integrated circuits. It is understood that the form of the invention shown and described in the detailed description and the drawings are to be taken merely as examples. It is intended that the following claims be interpreted broadly to embrace all the variations of the example embodiments disclosed.

Although the present invention and some of its advantages have been described in detail for some embodiments, it should be understood that various changes, substitutions and alterations can be made herein without departing from the spirit and scope of the invention as defined by the appended claims. Further, embodiments may achieve multiple objectives but not every embodiment falling within the scope of the attached claims will achieve every objective. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A circuit to reduce logic evaluation time in an integrated circuit, the circuit comprising:
a first circuit branch to evaluate a first logic input, wherein the first circuit branch is coupled to a first channel of a first transistor, wherein further a first gate of the first transistor is coupled to the first channel;
a second transistor to alter a voltage of an evaluation node in a second circuit branch, wherein a second gate of the second transistor is coupled to the first gate of the first transistor; and
an output circuit coupled to the evaluation node, wherein the output circuit comprises a third transistor having a third gate coupled to a fourth gate of a fourth transistor, wherein further the third gate is coupled to a second channel of the third transistor.

2. The circuit of claim 1, further comprising a third circuit branch coupled to the output circuit, the third circuit branch to evaluate a second logic input in conjunction with the first circuit branch.

3. The circuit of claim 2, wherein the first circuit branch is arranged to evaluate high fan-in AND logic inputs.

4. The circuit of claim 1, further comprising a fifth transistor coupled in parallel to the first transistor, the fifth transistor arranged to discharge an accumulated voltage of the first transistor.

5. The circuit of claim 1, wherein the first transistor comprises an n-MOS transistor.

6. The circuit of claim 1, wherein the output circuit comprises an inverter.

7. The circuit of claim 1, wherein the third transistor comprises a p-MOS transistor.

8. An apparatus to reduce logic evaluation time in an integrated circuit, the apparatus comprising:
a first logic module;
a first current mirror coupled to the first logic module, wherein the first current mirror is arranged to discharge an evaluation node of the first logic module; and
an output module coupled to the first logic module, wherein the output module comprises a second current mirror.

9. The apparatus of claim 8, further comprising a capacitance reduction module coupled to the first current mirror.

10. The apparatus of claim 8, further comprising a second logic module coupled to the output module, wherein the second logic module is arranged to evaluate logic in parallel with the first logic module.

11. The apparatus of claim 10, wherein the second logic module is arranged to evaluate high fan-in AND logic inputs.

12. The apparatus of claim 8, wherein the first logic module is arranged to evaluate high fan-in NAND logic inputs.

13. A method of increasing a rate of logic evaluation in an integrated circuit, the method comprising:
evaluating logic of at least one circuit branch;
discharging an evaluation node coupled to a first current mirror based upon the logic evaluation; and
switching a state of an output circuit via a second current mirror, wherein the output circuit is coupled to the at least one circuit branch.

14. The method of claim 13, further comprising discharging an accumulated voltage of the first current mirror when the at least one circuit branch pre-charges.

15. The method of claim 13, wherein evaluating logic of the at least one circuit branch comprises charging the evaluation node and conditionally discharging the evaluation node via the first current mirror.

16. The method of claim 13, wherein evaluating logic of the at least one circuit branch comprises evaluating logic of at least two parallel circuit branches.

17. The method of claim 16, wherein evaluating logic of at least two parallel circuit branches comprises evaluating logic for at least two parallel circuit branches of high fan-in AND gates.

18. A system, comprising:
a power supply;
an integrated circuit coupled to the power supply, wherein the integrated circuit comprises a dynamic logic circuit, wherein further the dynamic logic circuit comprises:
at least two circuit branches to evaluate logic in parallel;
a first current mirror coupled to one of the at least two circuit branches; and
an output circuit coupled to the at least two circuit branches, wherein the output circuit comprises a second current mirror.

19. The system of claim 18, wherein the integrated circuit is one of a processor and an ASIC.

20. The system of claim 18, wherein the dynamic logic circuit comprises a domino logic circuit arranged to evaluate AND logic inputs.
